(19) United States
(12) Patent Application Publication
(10) Pub. No.: US 2008/0106193 A1
(43) Pub. Date: May 8, 2008

(54) Organic light emitting display device and method of fabricating the same

(76) Inventors: Woo-Sik Jun, Suwon-si (KR); Kyung-Jin Yoo, Suwon-si (KR); Jong-Hyun Choi, Suwon-si (KR); Choong-Youl Im, Suwon-si (KR); Do-Hyun Kwon, Suwon-si (KR)

Correspondence Address: CHRISTIE, PARKER & HALE, LLP, PO BOX 7068, PASADENA, CA, 91109-7068, US

(21) Appl. No.: 11/982,470

(22) Filed: Oct. 31, 2007

(30) Foreign Application Priority Data
Nov. 3, 2006 (KR) 10-2006-0108492

(51) Int. Cl. H01J 63/04; H01J 9/00; H01L 51/00

(52) U.S. Cl. 313/504; 257/40; 445/24; 257/E51.022

(57) ABSTRACT

An organic light emitting display device in which a failure rate is reduced and thus product yield is improved, and a method of fabricating the same. The organic light emitting display device includes: a substrate; a thin film transistor disposed on the substrate, the thin film transistor including a semiconductor layer, a gate electrode, and source and drain electrodes; a first insulating layer disposed on the thin film transistor; an inorganic planarization layer disposed on the first insulating layer; a second insulating layer disposed on the inorganic planarization layer; a first electrode disposed on the second insulating layer, and electrically connected to the source and drain electrodes; an organic layer disposed on the first electrode, the organic layer including an emissive layer; and a second electrode disposed on the organic layer.

### CROSS-REFERENCE TO RELATED APPLICATION

This application claims priority to and the benefit of Korean Patent Application No. 10-2006-0108492, filed Nov. 3, 2006, the entire content of which is incorporated herein by reference.

### BACKGROUND OF THE INVENTION

1. Field of the Invention

The present invention relates to an organic light emitting display device in which a failure rate is reduced to thereby improve product yield, and a method of fabricating the same.

2. Description of Related Art

Organic light emitting display devices are display devices using a phenomenon in which electrons and holes injected into an organic material thin film through a cathode and an anode are recombined to form excitons, and light having a specific wavelength is emitted by energy generated from the excitons.

Compared to liquid crystal displays (LCDs), organic light emitting display devices have faster response speed, and thus they can better display moving pictures. Moreover, the organic light emitting display devices are self-emission devices and have a relatively wide viewing angle and a relatively high brightness.

In one embodiment, an organic light emitting display device is formed in a stacked structure. The stacked structure can realize a relatively high emission efficiency from the recombination of electrons and holes.

FIG. 1 is a cross-sectional view of a conventional organic light emitting display device.

Referring to FIG. 1, a substrate 100 having a buffer layer 105 thereon is provided, and a semiconductor layer 110 is formed on the buffer layer 105.

A gate insulating layer 115 is formed on the substrate 100 and on the semiconductor layer 110, and a gate electrode 120 is formed on the gate insulating layer 115 in a region corresponding to the semiconductor layer 110. Source and drain regions 110a and 110b are formed in the semiconductor layer 110 by performing an ion doping process using the gate electrode 120 as a mask.

In addition, an interlayer insulating layer 125 is formed on the substrate 100 and on the gate electrode 120, and then etched to form contact holes 125a for exposing the source and drain regions 110a and 110b.

Source and drain electrodes 130 electrically connected to the source and drain regions 110a and 110b through the contact holes 125a are also formed in the organic light emitting display device of FIG. 1.

An inorganic planarization layer 140 including silicate on glass(SOG) is formed on the substrate 100 and on the source and drain electrodes 130, and then etched to form a via hole 140a for exposing one of the source electrode 130 or the drain electrode 130 in the planarization layer 140.

A first electrode 150 electrically connected to the one of the source electrode 130 or the drain electrode 130 through the via hole 140a is formed. Then, a pixel defining layer 155 is formed on the first electrode 150, and then patterned to form an opening 155a.

An organic layer 160 including an emissive layer is formed on the first electrode 150, and a second electrode 165 is formed on the organic layer 160, and thus a formation of the organic light emitting display device of FIG. 1 is completed.

However, an inorganic planarization layer of a conventional organic light emitting display device does not have good adhesion to underlying layers, such as source and drain electrodes, so that a peeling off phenomenon may occur, thereby causing a defect. Also, in the inorganic planarization layer, discoloration and cracks may occur due to a stripping solution used in a subsequent process for forming a first electrode, thereby causing a further defect in the conventional organic light emitting display.

### SUMMARY OF THE INVENTION

Aspects of the present invention are directed to an organic light emitting display device including a first insulating layer, an inorganic planarization layer and a second insulating layer, and a method of fabricating the same.

Aspects of the present invention are direct to an organic light emitting display device, in which a first insulating layer having good adhesion to source and drain electrodes is formed under an inorganic planarization layer, and a second insulating layer is formed on the inorganic planarization layer to protect the inorganic planarization layer in a subsequent process, thereby reducing (or preventing) defects and improving product yield, and a method of fabricating the same.

In an exemplary embodiment of the present invention, an organic light emitting display device includes: a substrate; a thin film transistor disposed on the substrate, the thin film transistor including a semiconductor layer, a gate electrode, and source and drain electrodes; a first insulating layer disposed on the thin film transistor; an inorganic planarization layer disposed on the first insulating layer; a second insulating layer disposed on the inorganic planarization layer; a first electrode disposed on the second insulating layer, and electrically connected to the source and drain electrodes; an organic layer disposed on the first electrode, the organic layer including an emissive layer; and a second electrode disposed on the organic layer.

In another exemplary embodiment of the present invention, a method of fabricating an organic light emitting display device includes: forming a thin film transistor including a semiconductor layer, a gate electrode, and source and drain electrodes on a substrate; forming a first insulating layer on the thin film transistor; forming an inorganic planarization layer on the first insulating layer; forming a second insulating layer on the inorganic planarization layer; forming a via hole for exposing the source and drain electrodes in the first insulating layer, in the inorganic planarization layer, and in the second insulating layer; forming a first electrode electrically connected to the source and drain electrodes through the via hole; forming an organic layer including an emissive layer on the first electrode; and forming a second electrode on the organic layer.

In another exemplary embodiment of the present invention, an organic light emitting display device includes: a thin film transistor; a first insulating layer; an inorganic planarization layer, the first insulating layer being disposed between and in contact with the thin film transistor and the inorganic planarization layer; a second insulating layer, the inorganic planarization layer being disposed between and in contact with the first insulating layer and the second insulating layer; a first electrode electrically connected to the thin film transistor, the second insulating layer being disposed between and in contact with the inorganic planarization layer and the first electrode; an organic layer including an emissive layer, the first electrode being disposed between and in contact with the second insulating layer and the organic layer; and a second electrode, the organic layer being disposed between and in contact with the first electrode and the second electrode.

### BRIEF DESCRIPTION OF THE DRAWINGS

The accompanying drawings, together with the specification, illustrate exemplary embodiments of the present invention, and, together with the description, serve to explain the principles of the present invention.

The patent or application file contains at least one drawing/picture executed in color. Copies of this patent or patent application publication with color drawing/picture(s) will be provided by the Office upon request and payment of the necessary fee.

The patent or application file contains at least one drawing/picture executed in color. Copies of this patent or patent application publication with color drawing/picture(s) will be provided by the Office upon request and payment of the necessary fee.

FIG. 1 is a cross-sectional view of a conventional organic light emitting display device.

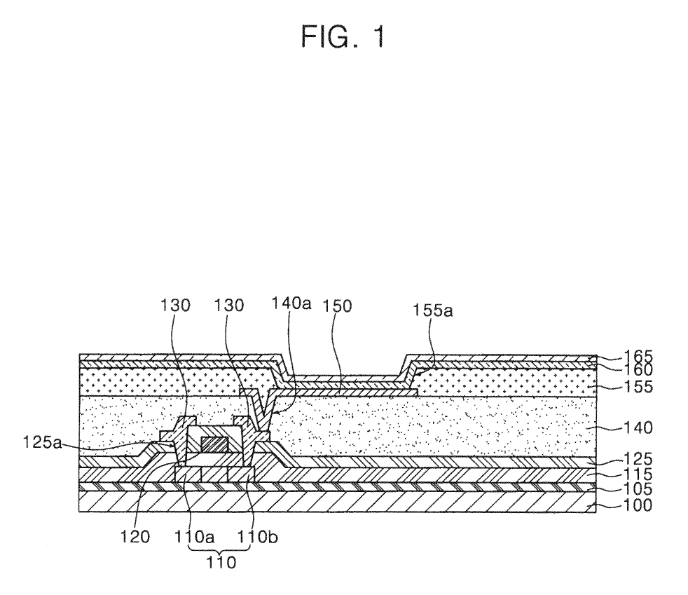

FIG. 2 is a cross-sectional view of an organic light emitting display device in accordance with an exemplary embodiment of the present invention.

FIG. 3A is a photograph showing a surface of a device in accordance with an Exemplary Embodiment after a stripping process.

FIG. 3B is a photograph showing a cross-section of the device in accordance with the Exemplary Embodiment after the stripping process.

FIG. 4A is a photograph showing a surface of a device in accordance with a Comparative Example after the stripping process.

FIG. 4B is a photograph showing a cross-section of the device in accordance with the Comparative Example after the stripping process.

### DETAILED DESCRIPTION

In the following detailed description, only certain exemplary embodiments of the present invention are shown and described, by way of illustration. As those skilled in the art would recognize, the invention may be embodied in many different forms and should not be construed as being limited to the embodiments set forth herein. Also, in the context of the present application, when an element is referred to as being “on” another element, it can be directly on the another element or be indirectly on the another element with one or more intervening elements interposed therebetween. Like reference numerals designate like elements throughout the specification. Also, in the drawings, the thicknesses of layers and regions may be exaggerated for ease and/or clarity of description purposes.

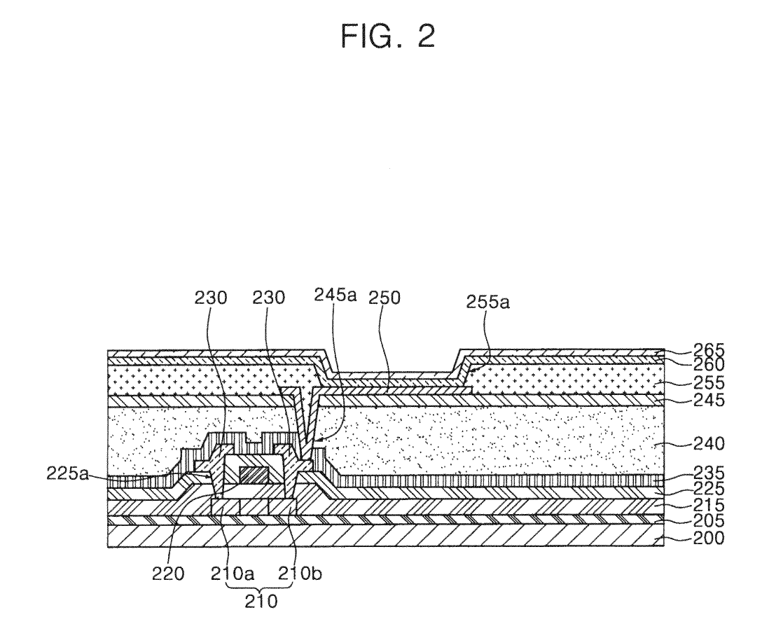

FIG. 2 is a cross-sectional view of an organic light emitting display device in accordance with an exemplary embodiment of the present invention.

Referring to FIG. 2, a buffer layer 205 is formed on a substrate 200, which is formed of, for example, glass, stainless steel and/or plastic. Here, the buffer layer 205 may be a silicon nitride layer, a silicon oxide layer, or a multi-layer thereof. The buffer layer 205 serves to reduce (or prevent) diffusion of moisture or impurities generated from the underlying substrate 200, or to assist in crystallization of a semiconductor layer, which will be formed in a subsequent process, by properly controlling a heat transmission speed.

An amorphous silicon layer is formed on the buffer layer 205, and then crystallized to form a polycrystalline or single crystal silicon layer. The silicon layer is patterned to form a semiconductor layer 210. The amorphous silicon layer may be formed by chemical vapor deposition (CVD) and/or physical vapor deposition (PVD). Also, during or after the formation of the amorphous silicon layer, a process for reducing a concentration of hydrogen by dehydrogenation may be performed. The amorphous silicon layer may be crystallized by rapid thermal annealing (RTA), solid phase crystallization (SPC), metal induced crystallization (MIC), metal induced lateral crystallization (MILC), super grain silicon (SGS), excimer laser crystallization (ELA), and/or sequential lateral solidification (SLS).

A gate insulating layer, which is a silicon oxide layer, a silicon nitride layer, or a multi-layer thereof, is formed on the substrate 200 and on the semiconductor layer 210, and a gate electrode material is formed on the gate insulating layer 215. The gate electrode can be formed from aluminum (Al), an Al alloy, molybdenum (Mo), or an Mo alloy. In one embodiment, the gate electrode material may be formed of a molybdenum-tungsten (MoW) alloy.

The gate electrode material is patterned to form a gate electrode 220, and source and drain regions 210a and 210b are formed in the semiconductor layer 210 by performing an ion doping process using the gate electrode 220 as a mask.

An interlayer insulating layer 225 is formed on the substrate 200 and on the gate electrode 220. Here, the interlayer insulating layer 225 may be a silicon nitride layer, a silicon oxide layer or a multi-layer thereof.

The interlayer insulating layer 225 is etched to form contact holes 225a for exposing the source and drain regions 210a and 210b. Source and drain electrodes 230 connected to the source and drain regions 210a and 210b through the contact holes 225 are also formed in the organic light emitting display device of FIG. 2. Here, the source and drain electrodes 230 may be formed of at least one material selected from the group consisting of Mo, W, MoW, tungsten silicide (WSi₂), Molybdenum silicide (MoSi₂), Al, and combinations thereof. Thus, a formation of a thin film transistor including the semiconductor layer 210, the gate electrode 220, and the source and drain electrodes 230 is completed.

A first insulating layer 235 is formed on the substrate 200 and on the source and drain electrodes 230. The first insulating layer 235 serves to protect the thin film transistor, and to improve an interface characteristic, i.e., adhesion between an inorganic planarization layer to be formed in a subsequent process and the source and drain electrodes 230, thereby significantly reducing a peeling off phenomenon of the inorganic planarization layer. The first insulating layer 235 may be a silicon oxide layer and/or a silicon nitride layer. Also, the first insulating layer 235 may be formed to a thickness from 100 to 3000 Å. In one embodiment, if the thickness is less than 100 Å, the first insulating layer 235 may not be uniformly formed on the underlying layers, such as the source and drain electrodes 230 and the interlayer insulating layer 225. By contrast, in another embodiment, if the thickness is more than 3000 Å, processing time and production cost may increase.

An inorganic planarization layer 240 including silicate on glass(SOG) is formed on the first insulating layer 235. The SOG is formed on the first insulating layer 235 by spin coating and includes (or is) a solution including a material selected from the group consisting of silica glass, siloxane polymer, alkyl silsesquioxane (MSQ) polymer, hydrogen silsesquioxane (HSQ) polymer, hydrogen alky silsesquioxane polymer, and combinations thereof. The inorganic planarization layer 240 may be formed to a thickness from 0.5 to 2 μm. In one embodiment, if the thickness is less than 0.5 μm, its flatness may be difficult to be maintained. By contrast, in another embodiment, if the thickness is more than 2 μm, processing time and production cost may increase. Here, the inorganic planarization layer may be formed to a thickness of 1 μm.

The inorganic planarization layer 240 is thermally treated. The thermal treatment may be performed for a time period ranging from 30 minutes to 4 hours at a temperature ranging from 200 to 500° C. This is because, in one embodiment, if the thermal treatment is performed for less than 30 minutes or below 200° C., the SOG cannot be hardened, and thereby moisture from the inside of the SOG may not be fully removed. By contrast, in another embodiment, if the thermal treatment is performed for more than 4 hours, or over 500° C., the substrate 200 may be damaged due to a stress applied to the substrate 200.

Also, in one embodiment, the thermal treatment as described above allows the underlying thin film transistor to be passivated by performing hydrogenation when the first insulating layer 235 is a silicon nitride layer.

In addition, a second insulating layer 245 including a silicon oxide layer and/or a silicon nitride layer is formed on the inorganic planarization layer 240. The second insulating layer 245 may be formed to a thickness ranging from 500 to 1000 Å. In one embodiment, if the thickness is less than 500 Å, the second insulating layer 245 may not be uniformly formed on the inorganic planarization layer 240 and may not also protect the inorganic planarization layer 240 from a stripping solution used in a subsequent process for forming a first electrode, and thus the inorganic planarization layer 240 may be discolored or cracked. By contrast, in another embodiment, if the thickness is more than 1000 Å, processing time and production cost may increase.

The first insulating layer 235, the inorganic planarization layer 240, and the second insulating layer 245 are etched, thereby forming a via hole 245a for exposing the drain electrode 230. A first electrode 250 connected to the drain electrode 230 through the via hole 245a is formed. Here, the first electrode 250 may be formed to have a dual or triple structure. The dual or triple structure includes a layer formed of ITO and/or IZO, which has a high work function, and a reflective layer. The reflective layer may be formed of Al, Ag, or alloys thereof.

A pixel defining layer 255 is formed on the first electrode 250 and then patterned, thereby forming an opening. The pixel defining layer 255 may be an organic layer, which is formed of at least one material selected from the group consisting of polyimide, benzocyclobutene series resin and acrylate, or an inorganic layer, such as SOG.

An organic layer 260 including an organic emissive layer is formed on the first electrode 250. The organic layer 260 may be formed by deposition, ink-jet printing and/or laser induced thermal imaging method. Also, the organic layer 260 may further include at least one layer selected from the group consisting of a hole injection layer, a hole transport layer, a hole blocking layer, an electron transport layer, and an electron injection layer.

A second electrode 265 is formed on the organic layer 260. The second electrode 265 is formed of silver (Ag), aluminum (Al), calcium (Ca), magnesium (Mg) or alloys thereof.

In addition, the substrate 200 is sealed with an encapsulating substrate using a sealant and/or frit, and thus a formation of the organic light emitting display device of FIG. 2 is completed.

The following Exemplary Embodiment and Comparative Example illustrate the present invention in more detail. However, the present invention is not limited by the Exemplary Embodiment or the Comparative Example.

### EXEMPLARY EMBODIMENT

A first insulating layer 335, formed of a silicon nitride layer, was formed to a thickness of 0.1 μm on a substrate and on a thin film transistor formed on the substrate, the thin film transistor including a semiconductor layer, a gate electrode, and source and drain electrodes 330. An inorganic planarization layer 340, formed of SOG, was formed to a thickness of 1 μm on the first insulating layer 335. Also, a second insulating layer 345, formed of a silicon nitride layer, was formed to a thickness of 500 Å on the inorganic planarization layer 340. The first insulating layer 340, the inorganic planarization layer 340, and the second insulating layer 345 were etched, thereby forming a via hole. A first electrode, formed of ITO, and connected to the source and drain electrodes through the via hole was formed to a thickness of 0.1 μm.

### COMPARATIVE EXAMPLE

A first insulating layer 435, formed of a silicon nitride layer, was formed to a thickness of 0.1 μm on a substrate and on a thin film transistor formed on the substrate, the thin film transistor including a semiconductor layer, a gate electrode, and source and drain electrodes 430. An inorganic planarization layer 440, formed of SOG, was formed to a thickness of 1 μm on the first insulating layer 435. The first insulating layer 435 and the inorganic planarization layer 440 were etched, thereby forming a via hole. A first electrode, formed of ITO, and connected to the source and drain electrodes through the via hole was formed to a thickness of 0.1 μm.

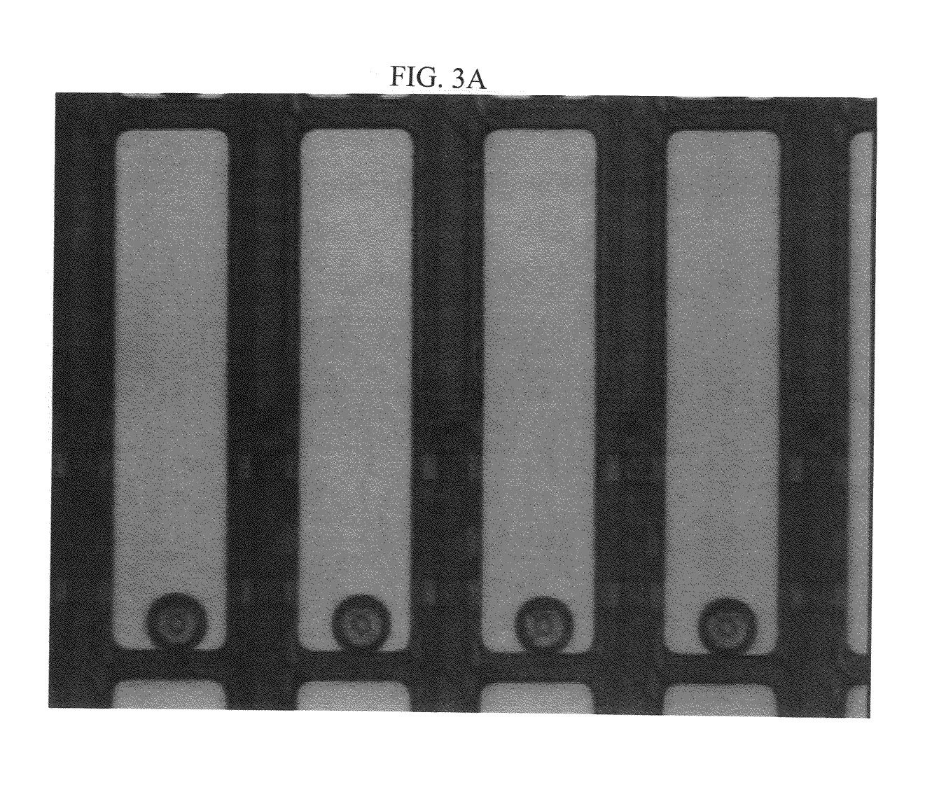

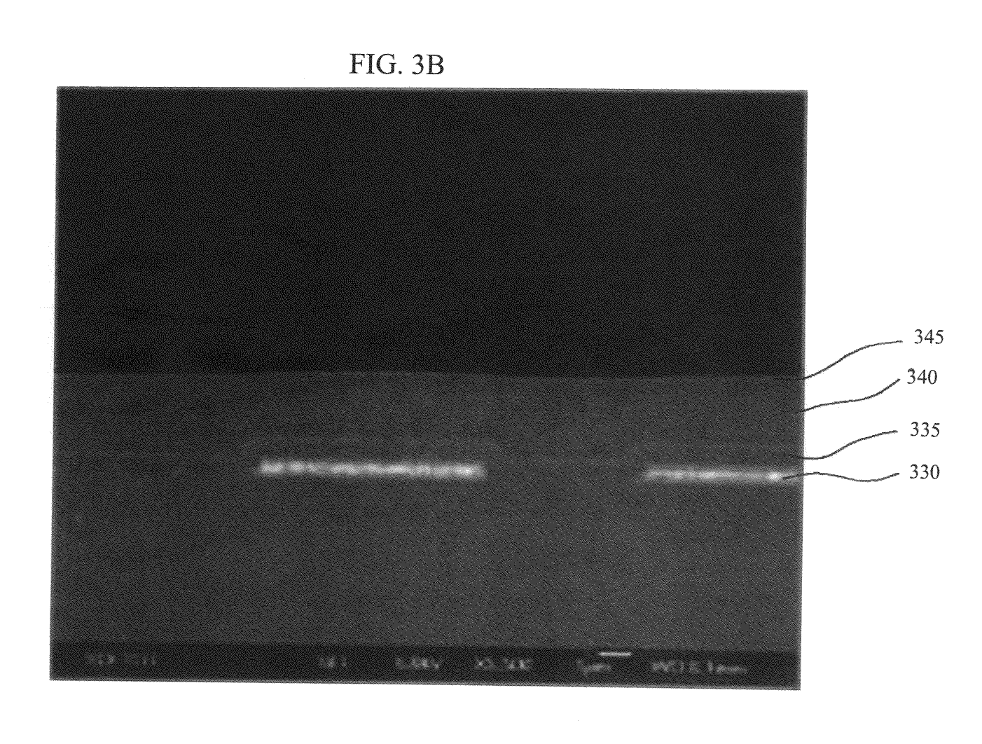

FIGS. 3A and 3B are photographs showing a surface and a cross-section of the Exemplary Embodiment.

Referring to FIG. 3A, it may be noted that after forming the first electrode, i.e., the ITO, since the second insulating layer 345 still protects the inorganic planarization layer 340, i.e., the SOG, loss of the SOG does not occur during a stripping process of the first electrode, and thus no stain exists.

Also, referring to FIG. 3B, it may be noted that the first insulating layer 335, the inorganic planarization layer 340, and the second insulating layer 345 are formed on the source and drain electrodes 330 without damage.

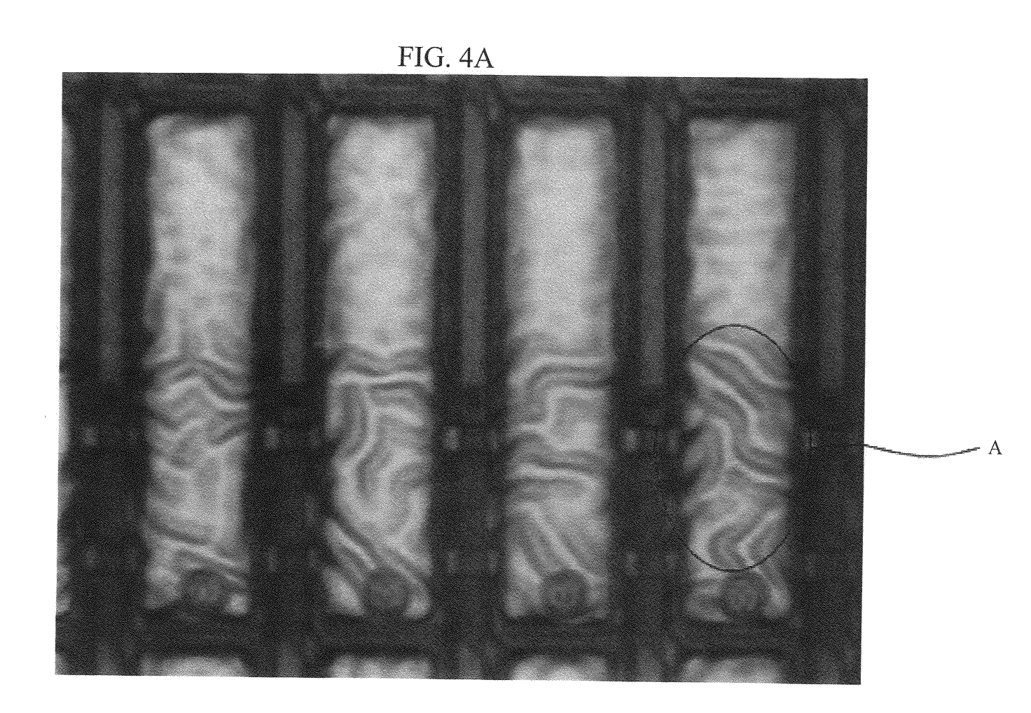

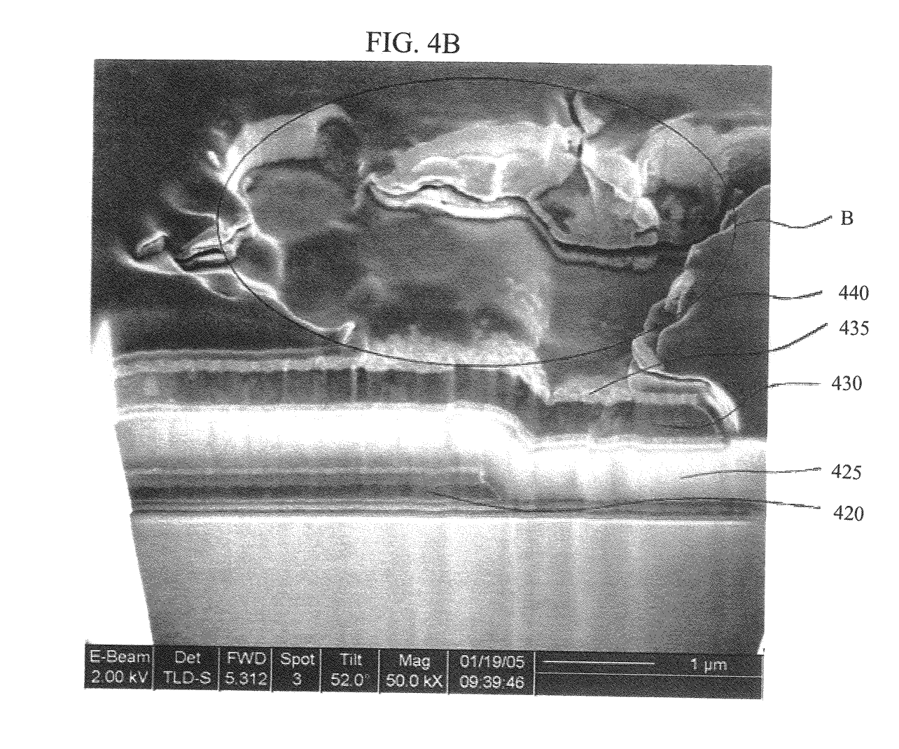

FIGS. 4A and 4B are photographs showing a plane and a cross-section of the Comparative Example.

Referring to FIG. 4A, it is noted that a stain A is generated due to the loss of the inorganic planarization layer 440, i.e., the SOG, which is under the first electrode. This is caused by a stripping solution used in patterning the first electrode, wherein when the stripping solution is in direct contact with the SOG, the SOG is lost due to degradation of a chemical resistant characteristic.

Referring to FIG. 4B, an interlayer insulating layer 425 is formed on a gate electrode 420, and the source and drain electrodes 430 are formed on the interlayer insulating layer 425. The first insulating layer 435 is formed on the source and drain electrodes 430, and the inorganic planarization layer 440, i.e., SOG, is formed on the first insulating layer 435. As described in FIG. 4A, it may be noted that the SOG is damaged (e.g., at region B) by the stripping solution.

In view of the foregoing, an organic light emitting display device in accordance with certain exemplary embodiments of the present invention has insulating layers on and under an inorganic planarization layer, thereby improving an interface characteristic between source and drain electrodes. Thus, a peeling off phenomenon of the inorganic planarization layer, and the discoloration and crack of the inorganic planarization layer, which are caused by a stripping solution used for patterning a first electrode, may be prevented.

While the invention has been described in connection with certain exemplary embodiments, it will be appreciated by those skilled in the art that the invention is not limited to the disclosed embodiments, but, on the contrary, is intended to cover various modifications included within the principles and spirit of the invention, the scope of which is defined in the claims and their equivalents.

What is claimed is:

1. An organic light emitting display device, comprising:
a substrate;
a thin film transistor disposed on the substrate, the thin film transistor including a semiconductor layer, a gate electrode, and source and drain electrodes;
a first insulating layer disposed on the thin film transistor;
an inorganic planarization layer disposed on the first insulating layer;
a second insulating layer disposed on the inorganic planarization layer;
a first electrode disposed on the second insulating layer, and electrically connected to the source and drain electrodes;
an organic layer disposed on the first electrode, the organic layer including an emissive layer; and
a second electrode disposed on the organic layer.

2. The organic light emitting display device according to claim 1, wherein each of the first and second insulating layers is a silicon nitride layer or a silicon oxide layer.

3. The organic light emitting display device according to claim 1, wherein the first insulating layer is formed to a thickness from about 100 to about 3000 Å.

4. The organic light emitting display device according to claim 1, wherein the inorganic planarization layer is formed of silicate on glass (SOG).

5. The organic light emitting display device according to claim 4, wherein the SOG comprises a material selected from the group consisting of silica glass, alkyl siloxane polymer, alkyl silsesquioxane polymer, hydrogen silsesquioxane polymer, hydrogen alkyl silsesquioxane polymer, and combinations thereof.

6. The organic light emitting display device according to claim 1, wherein the inorganic planarization layer is formed to a thickness from about 0.5 to about 2 μm.

7. The organic light emitting display device according to claim 1, wherein the second insulating layer is formed to a thickness from about 500 to about 1000 Å.

8. A method of fabricating an organic light emitting display device, the method comprising:
forming a thin film transistor including a semiconductor layer, a gate electrode, and source and drain electrodes on a substrate;
forming a first insulating layer on the thin film transistor,
forming an inorganic planarization layer on the first insulating layer;
forming a second insulating layer on the inorganic planarization layer;
forming a via hole for exposing the source and drain electrodes in the first insulating layer, in the inorganic planarization layer, and in the second insulating layer;
forming a first electrode electrically connected to the source and drain electrodes through the via hole;
forming an organic layer including an emissive layer on the first electrode; and
forming a second electrode on the organic layer.

9. The method according to claim 8, wherein each of the first and second insulating layers is formed of a silicon oxide layer or a silicon nitride layer.

10. The method according to claim 8, wherein the first insulating layer is formed to a thickness from about 100 to about 3000 Å.

11. The method according to claim 8, wherein the inorganic planarization layer is formed of silicate on glass (SOG).

12. The method according to claim 11, wherein the SOG comprises a material selected from the group consisting of silica glass, alkyl siloxane polymer, alkyl silsesquioxane polymer, hydrogen silsesquioxane polymer, hydrogen alkyl silsesquioxane polymer, and combinations thereof.

13. The method according to claim 8, wherein the inorganic planarization layer is formed to a thickness from about 0.5 to about 2 μm.

14. The method according to claim 8, wherein the inorganic planarization layer is formed on the first insulating layer by spin coating.

15. The method according to claim 8, wherein the second insulating layer is formed to a thickness from about 500 to about 1000 Å.

16. An organic light emitting display device, comprising:
a thin film transistor;
a first insulating layer;
an inorganic planarization layer, the first insulating layer being disposed between and in contact with the thin film transistor and the inorganic planarization layer;
a second insulating layer, the inorganic planarization layer being disposed between and in contact with the first insulating layer and the second insulating layer;
a first electrode electrically connected to the thin film transistor, the second insulating layer being disposed between and in contact with the inorganic planarization layer and the first electrode;
an organic layer including an emissive layer, the first electrode being disposed between and in contact with the second insulating layer and the organic layer; and
a second electrode, the organic layer being disposed between and in contact with the first electrode and the second electrode.

17. The organic light emitting display device according to claim 16, wherein each of the first and second insulating layers comprises a material selected from the group consisting of a silicon nitride layer, a silicon oxide layer, and combinations thereof.

18. The organic light emitting display device according to claim 16, wherein the first insulating layer is formed to a thickness from about 100 to about 3000 Å.

19. The organic light emitting display device according to claim 16, wherein the inorganic planarization layer is formed to a thickness from about 0.5 to about 2 μm.

20. The organic light emitting display device according to claim 16, wherein the second insulating layer is formed to a thickness from about 500 to about 1000 Å.
